(19) United States
(12) Patent Application Publication
(10) Pub. No.: US 2024/0006255 A1
(43) Pub. Date: Jan. 4, 2024

(54) METHOD FOR PRODUCING AN ELECTROTECHNICAL ARRANGEMENT, ELECTRONIC CONTROL UNIT AND ELECTROTECHNICAL ARRANGEMENT

(71) Applicant: Robert Bosch GmbH, Stuttgart (DE)

(72) Inventors: Ingo Fritsch, Wendlingen A.N. (DE); Wolfram Kienle, Magstadt (DE)

(21) Appl. No.: 18/254,251

(22) PCT Filed: Oct. 21, 2021
(86) PCT No.: PCT/EP2021/079221

§ 371 Date: May 24, 2023

(30) Foreign Application Priority Data
Nov. 27, 2020 (DE) 10 2020 214 989.5

(51) Int. Cl. H01L 23/04; H01L 23/13; H01L 23/32

(52) U.S. Cl. CPC H01L 23/04; H01L 23/13; H01L 23/32

(57) ABSTRACT

The invention relates to an electronic control unit, an electrotechnical arrangement, and a method for producing an electrotechnical arrangement. The electrotechnical arrangement (10) comprises a circuit substrate (3), an electrical component (2), and an insulating element (4); wherein the circuit substrate (3) is overmoulded with the insulating element (4), the insulating element (4) has a flank (5) which is aligned at an angle with respect to a direction Z defined perpendicularly to a surface of the circuit substrate (3), and the component (2) is fixed on the circuit substrate (3) at the foot of the flank (5) of the insulating element (4).

### BACKGROUND

The present invention relates to a method for producing an electrotechnical arrangement, an electronic control unit, and an electrotechnical arrangement. In particular, the present invention relates to a simple and inexpensive as well as exact placement with a circuit substrate for connecting electrical components.

Modern power substrates are based on a ceramic construction with metallic upper and lower surfaces. The circuit breakers (IGBT, MOSFET, etc.) are then assembled and wired. As a result of the substrate, a decompensation is only possible in the two-dimensional space. Bonds (tape, wire) are available as the external contact. Punched parts that are contacted by ultrasonics or laser welding are also used. These connecting elements are in this case already part of one of the joining partners.

There is a need for a method for positioning/centering connecting elements to be joined subsequently to the power substrate (“electrical on-board elements”). This positioning must be safe, reliable, and accurate. This is a precondition for a low-inductive design, as it is advantageous for switching modules with SiC MOSFETs.

### SUMMARY

The aforementioned need is met by an electrotechnical arrangement having the features of the invention.

The present design element is based on the concept of not designing the connection between the substrate-based module and the DC link capacitor during a production step, but rather obtaining a design that solves the aforementioned problems by separating the production steps. Existing requirements for air and creepage distances can also be varied or adjusted by way of this design element. The design element proposed herein provides for a position centering of the joining partner in the X and Y directions. Depending on the joining process, the connecting part is brought into its end position in the Z direction during the process. This centering principle (Z direction) is flexible for this purpose. The demoulding chamfer on the electronic component is used in this case as a catching funnel. This catching funnel can also adjust the creepage distance against electrical short circuit.

Stated another way, an electrotechnical arrangement is proposed comprising a circuit substrate (board) and at least one electrical component. For example, the electrical component can comprise a circuit breaker (IGBT, MOSFET, etc.). In addition, an insulating element is provided, which is provided on the edge side of the circuit substrate. The insulating element can in particular be provided as an electrical insulation between a top and a bottom side of the circuit substrate. The circuit substrate in this way is overmoulded with the insulating element. In this way, the circuit substrate can be understood or designed as at least approximately the frame surrounding the circuit substrate or as an enclosure of the circuit substrate. The insulating element has a direction Z defined perpendicularly on a surface of the circuit substrate, opposite to an angularly oriented flank. The flank could also be understood as a ramp, slope, or grade. The component is fixed to the foot of the flank of the insulating element on the circuit substrate. In particular, there is an electrical connection between the component and the circuit substrate in the region of the foot of the flank. However, at least the component comprises a section or structure arranged before and after the joining of the component on the circuit substrate or a conductor path located on the circuit substrate. In this way, the component is fixed to the circuit substrate by its section at the foot of the flank in a target position, while the component can have even higher positioning tolerances with respect to the circuit substrate during the course of approaching the circuit substrate (in upper regions of the flank). The flank basically defines a forced reduction of the positioning tolerances during the course of the component approaching the circuit substrate. The flank of the insulating element could therefore also be understood as a portion of a funnel or a positioning ramp. To the extent that the component is engaged with the flank of the insulating element in a predefined manner, it can only reach the target position during the course of approaching the circuit substrate. In particular, a flank-guided section of the component can be clamped between the flank and a further structure (e.g., a further flank on/in the insulating element) in order to thus take particularly low tolerances horizontally to the surface of the circuit substrate before it is glued, welded, soldered, or the like on the circuit substrate. For this purpose, the component can be pressed onto the circuit substrate, while the section located in the region of the flank of the foot is clamped by this process and optionally even forcibly deformed/biased. In particular, this part of the component can be decelerated by the friction on the flank, while other portions of the component continue to migrate towards the circuit substrate until they eventually come into contact with it and are electrically connected to it. The electrical connection can in particular be made with a pad or conductor path arranged on the circuit substrate. In this way, the insulating element provided for electrical insulation on the circuit substrate can also be used in order to facilitate a positioning of the electrical component on the circuit substrate.

The component can in particular comprise a stamped part, preferably a conductor path, for electrically contacting a predefined region on the circuit substrate. In particular, the region of the component to be arranged in the region of the foot of the flank can be designed elastically (in particular spring-elastically) in order to ensure exact positioning of the component with respect to the substrate before the electrical component is connected to the circuit substrate (electrically and/or mechanically). In other words, the electrical component slides at least proportionally down the flank during the production of the electrotechnical arrangement until the electrical component comes to rest on the circuit substrate at its target position due to the flank of the insulating element. For example, the flank can have a linear shape in order to keep frictional forces constant as the electrical component approaches the circuit substrate over the path Z.

A length of the flank can have at least 30%, preferably 80% or more of a thickness of the insulating element in the Z direction over the surface of the circuit substrate. In other words, the flank passes through the height of the insulating element in the Z direction at least 30%, preferably 80%, in particular 90% or more. In this way, relatively large initial positioning tolerances of the electrical component with respect to the circuit substrate can be eradicated solely due to the flank of the insulating element as the electrical component approaches the circuit substrate.

The overall thickness of the insulating element over a surface of the circuit substrate in the region of the flank can be at least 10 mm, preferably 20 mm, very preferably 30 mm, or can have ranges between the aforementioned values. The overall thickness of the insulating element over a surface of the circuit substrate in the region of the flank is then directed to the selected flank angle in cooperation with the production and component tolerance to be eliminated and, in this case, is usually between 3 mm and 30 mm, in particular at integer multiples of 1 mm in the aforementioned interval.

The insulating element can be provided as an electrical insulator in the arrangement. Said element can be provided in order to avoid creepage currents between an upper and a bottom of the circuit substrate. For this purpose, the insulating element circumscribes an edge/cutting edge of the circuit substrate at least in the region of the surfaces between which a significant voltage in the event of operation is to be expected. The insulating element basically encompasses the circuit substrate, for which reason flanks according to the invention can be provided at different edges of the circuit substrate in order to move the electrical component in the X/Y directions horizontally to the circuit substrate when the electrical component approaches the circuit substrate. The flank can be designed as a demoulding chamfer. In other words, the flank can also be provided to favor a demoulding of the insulating element out of a spray mould by means of which it has been injected onto the circuit substrate. Alternatively or additionally, the flank can be a portion of a catching funnel or a V-shaped groove. In this context, a funnel is not necessarily to be considered a hollow shape that tapers in sections, but rather can comprise, e.g., two substantially flat edges, which cause a respective displacement of the electrical component in different directions horizontally to the surface of the circuit substrate in order to bring the electrical component to its target position. The flank can have an angle with respect to the Z direction from 5° to 50°, preferably from 10° to 45°, particularly preferably between 12° and 40°. In this range, the frictional forces will also be compatible with the circuit substrate even in case of inaccurate initial positioning of the electrical component, while a sufficient reduction of the initial positioning tolerances can be achieved during the course of the joining process.

The electrotechnical arrangement according to the invention can comprise an additional flank, which forms a funnel in connection with the flank in the insulating element. For example, the orientation of the additional flank can be rotated relative to the flank in an azimuth direction on the surface of the circuit substrate. In particular, an orientation of the flank, which is rotated substantially by 90° about the Z direction, can ensure that the two flanks in cooperation can cause a positioning of the electrical component in both the X and Y directions.

A floor structure in the insulating element can be provided between the additional flank and the flank, which covers the surface of the circuit substrate. In other words, the floor of the catching funnel or the V-shaped groove is filled/covered by insulating material of the insulating element. Thus, at the end of the joining process, the flank/additional flank does not come into electrical/mechanical contact with the circuit substrate, but rather rests on the floor structure. This provides for a biasing of the electrical component in its end position on the circuit substrate. Alternatively or additionally, a structure of the electrical component can be clamped between the additional flank and the flank, as has already been carried out above. In this way, a zero tolerance-like positioning aid for the electrical component is provided. This ensures an exact positioning in the X and/or Y direction(s) even before the electrical component has reached its end position under contact with the circuit substrate.

Proposed according to a second aspect of the present invention is a method for producing an electrotechnical arrangement, as described in detail above in connection with the first aspect of the invention specified in the introductory section. According to the production method, a circuit substrate is first overmoulded with an insulating element. For this purpose in particular, the edge regions of the circuit substrate can be surrounded by an initially liquid or pasty mass, which subsequently foams and/or hardens in a spray form. The insulating element formed in this case can in particular have a height that is 1/20, preferably 1/10, very preferably ⅕, of a largest longitudinal extension of the dimension of the circuit substrate. An electrical component is then placed on the circuit substrate, with the component being placed on the circuit substrate during the course of a movement in the direction of a normal towards the surface of the circuit substrate (Z direction) and is aligned, due to a flank of the insulating element designed angularly to the Z direction, in a direction X and/or Y with respect to the circuit substrate, which direction is oriented perpendicular to the Z direction. In this context, the electrical component slides at least proportionally along the flank and thus lands on an end position (target position) predefined by the flank on the circuit substrate. In this context as well, the circuit substrate is understood to be a component that defines a mechanical end position of the electrical component without requiring that the circuit substrate may have no further components or conductor paths on which the electrical component is (proportionately) mounted. The features, combinations of features, and advantages resulting thereby in the method according to the invention for producing an electrotechnical arrangement correspond to those explained hereinabove in connection with the aspect of the invention specified in the introductory section, so reference is made to the above statements in order to avoid repetitions.

In a subsequent step, the electrical component can be mechanically and electrically (in particular galvanically) connected to the circuit substrate and/or a conductor path located thereon. The connection can be produced by, e.g., friction welding and/or sintering, and/or soldering, and/or welding, and/or riveting, and/or gluing. In this way, the electrical component is brought into a target position defined by the flank in the insulating element on the circuit substrate and subsequently connected to the circuit substrate for its intended function.

Proposed according to a third aspect of the present invention is an electronic control unit, which can, e.g., be provided and configured for use in an automobile on-board network. The electronic control unit comprises an electrotechnical arrangement according to the first aspect of the invention specified in the introductory section and is produced in particular according to a method according to the second aspect of the invention specified in the introductory section. The electronic control unit can, for example, be designed as a motor and/or transmission and/or gateway control unit. In particular, it can alternatively or additionally be configured for steering a means of propulsion. Further preferably, the electronic control unit can be provided for a power conversion in the on-board network of the propulsion means between a first voltage layer and a second voltage layer. Alternatively or additionally, the electronic control unit can be designed to convert power from three-phase electrical power into single-phase electrical power, or vice versa.

### BRIEF DESCRIPTION OF THE DRAWINGS

Exemplary embodiments of the invention are described in detail hereinafter with reference to the accompanying drawings. Shown are:

FIG. 1 a schematic illustration of a plan view of contact points of an exemplary embodiment of an electrotechnical contact arrangement;

FIG. 2 a schematic illustration of an overlapping contact of electrical components in an exemplary embodiment of an electrotechnical contact arrangement;

FIG. 3 a lateral view of two electrical components as the joining partners in an exemplary embodiment of an electrotechnical contact arrangement;

FIG. 4 a perspective illustration of an exemplary embodiment of an electrotechnical arrangement according to the invention;

FIG. 5 a perspective view of a further exemplary embodiment of an electrotechnical arrangement according to the invention;

FIG. 6 a lateral view of a further exemplary embodiment of an electrotechnical arrangement according to the invention;

FIG. 7 a lateral view of a further exemplary embodiment of an electrotechnical arrangement according to the invention;

FIG. 8 a sectional view of a sub-region of the electrotechnical arrangement shown in FIG. 6, and

FIG. 9 a flowchart illustrating steps of an exemplary embodiment of a method according to the invention for producing an electrotechnical arrangement.

### DETAILED DESCRIPTION

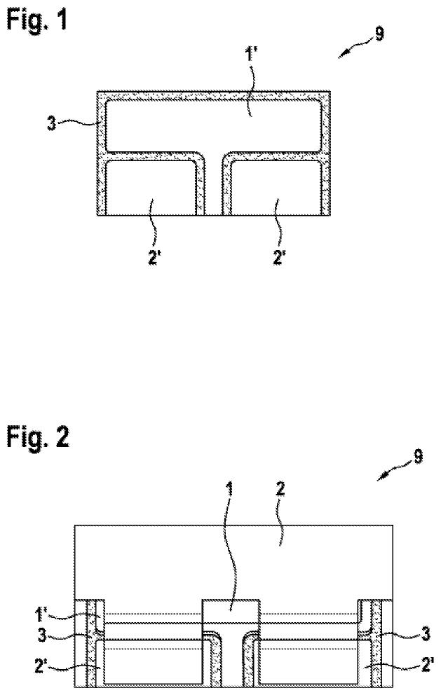

FIG. 1 shows a plan view of a substrate 3 on which contact points 1′, 2′ for contacting electrical components 1, 2 are arranged. The electrical component 1 comprises an electrical supply system that passes electrically in isolation between the two contact points 1′, 2′ for the electrical component 2. The contact points 1′, 2′ have a substantially rectangular shape. However, their corners are rounded. An insulating trench is provided between the contact points 1′, 2′, which has a width of approximately ⅕ to 1/7 of the shortest extension of the contact points 1′, 2′ for the electrical components 1, 2.

FIG. 2 shows a plan view of the arrangement shown in FIG. 1 after the contacting of the contact points 1′, 2′ by electrical components 1, 2. An exact positioning of the electrical components 1, 2 on the contact points 1′, 2′ is required, among other things, in order to not accidentally bridge the insulating trench located between the contact points 1, 2′.

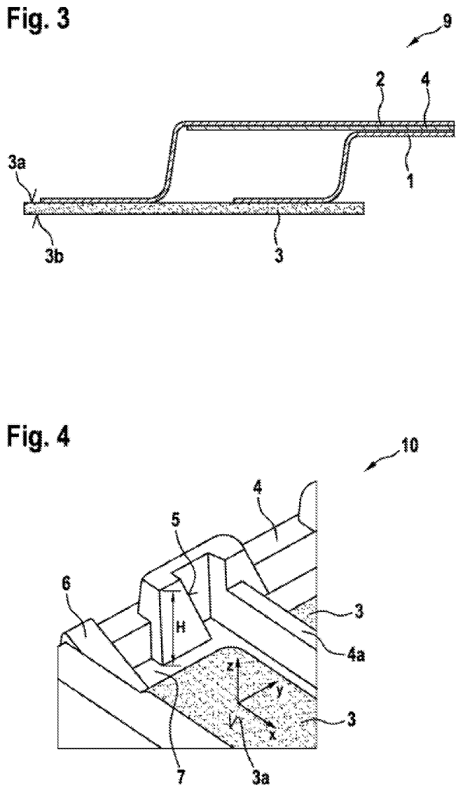

FIG. 3 shows a side view of the contact arrangement 9 (see FIG. 1, FIG. 2), in which the spatial relationship between the electrical components 1, 2 above the circuit substrate 3 can be seen. On their respective contact points 1′, 2′ (not shown in this case), the electrical components 1, 2 are, e.g., electrically and mechanically connected by friction welding. From the contact points 1′, 2′, curved structures of the electrical components 1, 2 stand out in an approximately vertical direction from the circuit substrate 3, in order to subsequently transition to a horizontal again at a height similar to one another. An insulating element 4 is attached to the bottom of the electrical component 2 so that the common derivation of the electrical components 1, 2 does not lead to an electrical connection of the two electrical components 1, 2.

FIG. 4 shows an electrotechnical arrangement 10 according to a first exemplary embodiment of the present invention, in which a circuit substrate 3 is overmoulded on the edge side by an insulating element 4. In this way, a voltage which may prevail on the top 3a of the circuit substrate 3 is electrically insulated by the insulating element 4 against a voltage which may prevail on a bottom (not shown). The insulating element 4 has a maximum height H in order to provide a comparatively large insulating distance from the top 3a to the bottom, which reduces any creepage currents. A rib 4a is also shaped from the insulating element 4, which connects opposite edges of the circuit substrate 3 and thus favors an electrical insulation of two regions on the surface 3a of the circuit substrate 3. A first flank 5 is provided in the manner according to the invention, which forms a positioning funnel with a flank that is perpendicular and counter to the Y direction of the flank 5. A structure introduced in the negative Z direction in this catching funnel would thus reach a specific target position without an external guiding of the electrical component being required for this purpose. In other words, in particular in the Y direction, a target end position is defined by the flank 5 or the catching funnel defined by it. The same applies for an additional flank 6, which defines a chamfer decreasing in the X direction. With a corresponding opposite flank (not shown), the additional flank 6 can thus define a predefined target position with the electric components 1, 2 to be connected to the circuit substrate 3 in the X direction. With respect to the Z axis, the orientations of the flank 5 and the additional flank 6 are oriented 90° with respect to one another in the mathematically negative rotational sense. The same can be true of the respective catching funnels or grooves, which result in connection with the flank 5 or the additional flank 6. Of course, the flank 5 and the additional flank 6 can also be combined together in a common catching funnel so that one and the same structure of the electrical component 1, 2 is guided into its end position by both the flank 5 and the additional flank 6. The floor of the respective catching funnel is covered by a flat layer of the insulating element 4 in the form of a floor structure. The circuit substrate is insulated on the surface at this location. As a result, creepage currents from a surface region 3a of the circuit substrate 3 to a further surface region 3b of the circuit substrate 3 can be suppressed or reduced. In particular, if the insulating element 4 comprises an elastic material, the floor structure 7 can lead in its end position to a biasing of the electrical component 1, 2 opposite the circuit substrate 3. Vibrations leading to disruptive noises can thereby be avoided.

A width of the flank 5 or the additional flank 6 can be in a range between 2 mm and 20 mm, preferably between 3 and 15 mm, very preferably between 5 and 10 mm. The width refers to a dimension of the flank 5 or additional flank 6 running at a right angle to the downward direction.

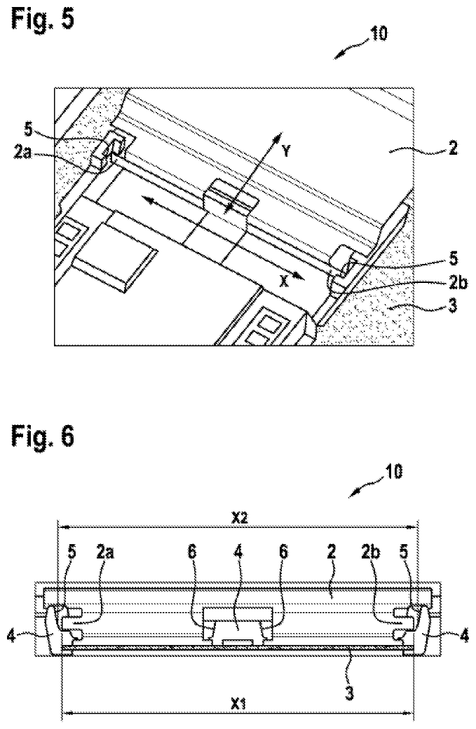

FIG. 5 shows a perspective illustration of an alternative exemplary embodiment of an electrotechnical arrangement 10 according to the invention. A component 2 made of a punched plate in this case comprises two tabs, which are mechanically and electrically connected to the substrate 3 by double bending at a right angle in opposite directions, as shown in the contact arrangement 9 according to FIG. 3. Two structures 2a, 2b projecting from the vertical regions of the tabs were guided by the catching funnels comprising a respective flank 5 in a respective target position, so that they were precisely positioned on the circuit substrate 3 with respect to the X and Y directions even before fixation.

FIG. 6 shows a sectional view of the arrangement shown in FIG. 5, which shows the cross-sections of the insulating element 4 in the region of contact between the tabs of the electrical component 2 and the circuit substrate 3. Stated another way, the cross-sectional view is correspondingly created substantially at a position of the double arrow X in FIG. 5. The regions of the insulating element 4 encompassing the circuit substrate 3 on the edge side surround the bottom of the circuit substrate 3 with a comparatively flat structure, while the insulating element 4 in the region of the top of the circuit substrate 3 forms the flanks 5 according to the invention in order to guide the structures 2a, 2b of the electrical component 2 and to position them substantially without clearance. In the X direction, the stamping part tolerance is indicated by double arrow X1, while the moulding body tolerance is indicated by X2. Due to the dimensions of X1 with respect to X2, the tolerance in the end position of the electrical component 2 can be predefined. A region of the insulating element 4 arranged centrally on the circuit substrate 3 has two additional edges 6, which, in conjunction with the outer flanks 5, cause an exact positioning of the electrical component 2 on the circuit substrate 3.

The punched part and the moulding body also have a respective production tolerance (sample scattering) as well as a mutual tolerance in the Y direction. In other words, the punched part thickness (Y1) can deviate from or vary from the V groove opening and thus enable or hinder an exact positioning.

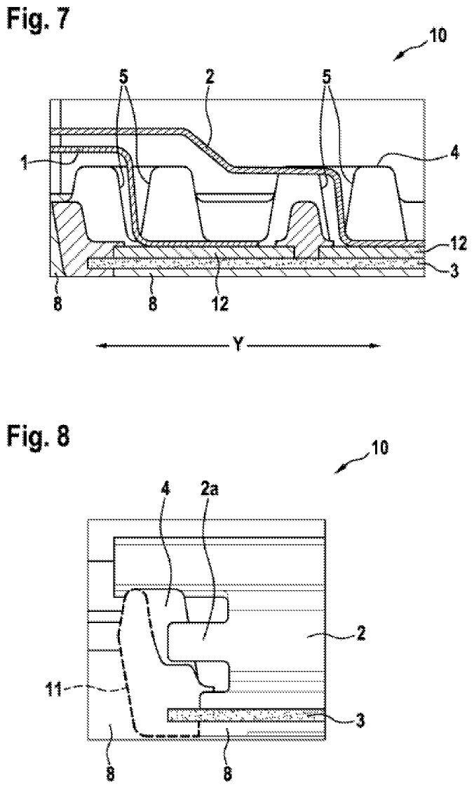

FIG. 7 shows a lateral cross-sectional view of the exemplary embodiment of an electrotechnical arrangement 10 shown in FIG. 5. In this exemplary embodiment, the structures (not shown) of the substantially vertical sections of the electrical components 1, 2 are arranged in a respective catching funnel between two oppositely inclined flanks 5 and are thus defined with respect to the circuit substrate 3. The electrical component 1 transitions from a horizontal fastening tab fastened to a conductor path 12 to the above-mentioned substantially vertical structure. Repeated bending at almost 90° transfers the electrical component 1 into the horizontal, whereby in this region it runs parallel to the circuit substrate 3. The same applies to the second electrical component 2, while it has however a slope of about 40° compared to the horizontal within its upper horizontal range. Two electrically insulated conductor path sections 12 are separated from one another by a structure of the insulating element 4, so that the creepage current distance between the conductor path sections 12 is significantly extended compared to a horizontal connection (e.g., via a surface of the circuit substrate 3).

FIG. 8 shows an enlarged view of the left edge region of the electrotechnical arrangement 10 presented in FIG. 6, which shows the significant extension of the creepage current section 11 between a structure 2a of the electrical component 2 and a bottom of the circuit substrate 3. In addition, the circuit substrate 3 along with the insulating element 4 is inserted into a housing 8. If the circuit substrate 3 and the electrical component 2 are previously positioned in the housing 8, the spraying process can define and/or strain and/or glue the aforementioned components in the housing 8 when the insulating element 4 is produced. In this case, an additional screw connection or other fastening can preferably be omitted.

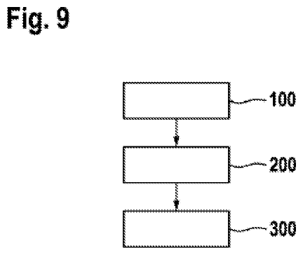

FIG. 9 shows steps of an exemplary embodiment of a method according to the invention for producing an electrotechnical arrangement. The electrotechnical arrangement can be a portion of an electrical control device or can be comprised by it. In a first step 100, a circuit substrate is overmoulded with an insulating element. In particular, the circuit substrate is overmoulded on the edge side with the insulating element. The insulating element can be or can comprise a foaming plastic. In this way, a determination of the circuit substrate by means of the insulating element is also possible in its periphery. In step 200, an electrical component is subsequently placed on the circuit substrate. The component is guided during the course of a movement in the Z direction (perpendicular to a surface of the circuit substrate) towards the circuit substrate. In order to be able to minimize effort with regard to handling of the electrical component, the electrical component is aligned by a flank of the insulating element being designed at an angle to the Z direction in a direction X and/or Y with respect to the circuit substrate, which direction is oriented perpendicular to the Z direction. In other words, the electrical component slides as necessary along the flank of the insulating element into a position nearest the circuit substrate, where the electrical component remains when used as intended and is electrically and/or mechanically connected to the circuit substrate. In step 300, the component is subsequently mechanically and electrically connected to the circuit substrate. In this case, material-locking, and/or positive-locking, and/or friction-locking methods can be used. In particular, a galvanic connection, optionally a frictional weld joint, a soldering operation, or a sintering operation can be used.

1. An electrotechnical arrangement (10) comprising
a circuit substrate (3),
an electrical component (1, 2), and
an insulating element (4),
wherein the circuit substrate (3) is overmoulded with the insulating element (4),
the insulating element (4) has a flank (5) which is aligned at an angle with respect to a direction Z defined perpendicularly to a surface of the circuit substrate (3),
and the component (1, 2) is fixed on the circuit substrate (3) at the foot of the flank (5) of the insulating element (4).

2. The electrotechnical arrangement according to claim 1, wherein the component (3) comprises a conductor path, which is configured to slide to the foot of the flank (5) along the flank (5) of the insulating element (4) during the course of the production of the electrotechnical arrangement (10) before being fixed.

3. The electrotechnical arrangement according to claim 1, wherein a length of the flank (5) is at least 80 percent of a thickness (H) of the insulating element (4) in Z over the surface of the circuit substrate (3).

4. The electrotechnical arrangement according to claim 1, wherein the thickness (H) of the insulating element (4) over a surface of the circuit substrate (3) in the region of the flank (5) is at least 3 mm.

5. The electrotechnical arrangement according to claim 1, wherein the insulating element (4) is provided as an electrical insulator in the arrangement (10) between a first surface (3a) of the circuit substrate (3) and a second surface (3b) of the circuit substrate (3) opposite the first surface.

6. The electrotechnical arrangement according to claim 1, wherein the flank (5)
is designed as a demoulding chamfer and/or
is a portion
of a catching funnel or
of a V-shaped groove

7. The electrotechnical arrangement according to claim 1, wherein the flank (5) has an angle with respect to the direction Z of 12° to 40°.

8. The electrotechnical arrangement according to claim 1, wherein an additional flank (6) is provided, which
forms a funnel with the flank (5) and/or
is arranged rotated substantially by 90 degrees about Z with respect to the flank (5).

9. The electrotechnical arrangement according to claim 8, wherein, between the additional flank (6) and the flank (5)
a floor structure (7) of the insulating element (4) is provided, which covers the surface of the circuit substrate (3) and/or
a structure of the electrical component (1, 2) is clamped.

10. A method for producing an electrotechnical arrangement, comprising the following steps:
overmoulding (100) a circuit substrate (3) with an insulating element (4),
placing (200) an electrical component (1, 2) on the circuit substrate (3), wherein the component (1, 2), during the course of a movement towards the circuit substrate (3) in the direction Z being perpendicular on a surface of the circuit substrate (3), is aligned, due to a flank (5) of the insulating element (4) designed angularly to the direction Z, in a direction X and/or Y with respect to the circuit substrate (3), which direction is oriented perpendicular to the direction Z.

11. The method according to claim 10, further comprising the following step:
mechanical and electrical connection (300) of the component (1, 2) to the circuit substrate (3).

12. The method according to claim 10, wherein, when the electrotechnical arrangement is used as intended, the insulating element (4) remains therein.

13. The method according to claim 10, wherein the component (1, 2) comprises a punched part which slides along the flank (5) of the insulating element (4).

14. The method according to claim 10, wherein a length of the flank (5) is at least 80 percent of a thickness of the insulating element (4) in Z over the surface of the circuit substrate (3).

15. The method according to claim 10, wherein the thickness (H) of the insulating element (4) over the surface of the circuit substrate (3) in the region of the flank (5) is at least 3 mm, preferably 30 mm.

16. The method according to claim 10, wherein the insulating element (4) is used as an electrical insulator in the arrangement (10) between a first surface (3a) of the circuit substrate (3) and a second surface (3b) opposite to the first surface (3a) of the circuit substrate (3).

17. The method according to claim 10, wherein the flank
is designed as a demoulding chamfer and/or
is a portion
of a catching funnel or
of a V-shaped groove.

18. The method according to claim 10, wherein the flank (5) has an angle with respect to the direction Z of 12° to 40°.

19. An electronic control unit comprising an electrotechnical arrangement (10) according to claim 1.
